(19) United States
(12) Patent Application Publication
(10) Pub. No.: US 2015/0181714 A1
(43) Pub. Date: Jun. 25, 2015

(54) SYSTEMS AND METHODS FOR CONTINUOUS FLASH LAMP SINTERING

(71) Applicant: Xenon Corporation, Wilmington, MA (US)

(72) Inventors: Saad AHMED, Wilmington, MA (US); Scott B. MOORE, Medway, MA (US); Rezaoul KARIM, Medford, MA (US)

(21) Appl. No.: 14/577,501

(22) Filed: Dec. 19, 2014

Related U.S. Application Data
(60) Provisional application No. 61/919,143, filed on Dec. 20, 2013.

(51) Int. Cl. H05K 3/00; H05B 41/34; B05D 3/02

(52) U.S. Cl. CPC H05K 3/00; B05D 3/0254; H05B 41/34; H05K 2203/10; H05K 2203/1131

(57) ABSTRACT

A flash lamp system for providing at least one continuous flash lamp pulse including at least two stages for sintering. The pulse can include a first portion for a first time period to reach a first peak energy level, and a second portion for a second time period to reach a second peak energy level. The one or more pulses have sufficient energy to sinter the layer of particles such that the printed electronic circuit is conductive.

### CROSS REFERENCES TO RELATED APPLICATIONS

This application claims priority under 35 U.S.C. 119(e) to U.S. Provisional Application No. 61/919,143, filed Dec. 20, 2013, entitled “Dual Mode Flash Lamp Sintering,” which is incorporated by reference herein in its entirety.

This application relates to the following applications, the contents of which are herein incorporated in their entirety: U.S. patent application Ser. No. 13/188,172 entitled “Reduction of Stray Light During Sintering,” filed on Jul. 21, 2011, and published as U.S. Publication No. 2012/0017829; and U.S. patent application Ser. No. 13/586,125 entitled “Sintering Process and Apparatus,” filed on Aug. 15, 2012, and published as U.S. Publication No. 2013/0043221.

### BACKGROUND

This disclosure relates to systems and methods for sintering.

Conventional sintering systems and methods can require high temperatures. When sintering a metallic material on a substrate, if high temperatures are used, the heat can damage the substrate. Metallic inks with very small particles, such as nanoparticle size (less than a nanometer in diameter average), can be sintered at lower temperatures than bulk metal. A sintering system can thus use pulsed light with a flash lamp and/or high intensity continuous light to sinter the particles together using lower temperatures than those used with conventional sintering systems.

Sintering has broad applications, such as in the emerging field of printed electronics. With printed electronics, functional electrical devices, including, but not limited to, lighting devices, batteries, super capacitors, and solar cells, are printed onto a substrate with a metallic ink using conventional printing methods. Printing electronic devices can be less costly and more efficient than using conventional methods for producing such devices.

### SUMMARY

Systems and methods of sintering are disclosed. In some aspects, the systems and methods include exposing a printed electronic circuit including a layer of small particles (e.g., nanoparticles) to at least one continuous flash lamp pulse that has at least two different stages. In some aspects, the exposing can include, for each pulse, providing a first portion of the pulse to the printed electronic circuit for a first time period to reach a first peak energy level, and providing a second portion of the pulse to the printed electronic circuit for a second time period to reach a second peak energy level, wherein the first peak energy level differs from the second peak energy level. In some aspects, the one or more pulses have sufficient energy to sinter the layer of nanoparticles such that the printed electronic circuit is conductive.

In some aspects, the first peak energy level is higher than the second peak energy level of the continuous pulse. In some aspects, the first portion of the continuous pulse is sufficient to sinter an upper portion of a layer of nanoparticles, and the second portion of the continuous pulse is sufficient to sinter a lower portion of the layer of nanoparticles and is sufficient to maintain a low sintering temperature. In some aspects, the low sintering temperature ranges from 200 to 400 degrees Celsius. In some aspects, the first peak energy level of the first portion ranges from 1.5 times to 10 times the second peak energy level of the second portion of the continuous pulse. In some aspects, the first time period ranges from about 0.1 milliseconds to 10 milliseconds, and the second time period ranges from about 0.1 milliseconds to 20 milliseconds. In some aspects, the first peak energy level is lower than the second peak energy level of the continuous pulse. In some aspects, the systems and methods further include providing, prior to the first stage of the continuous pulse, a relatively short, high peak energy starter pulse to start up the flash lamp when an energy pulse corresponding to the first peak energy level of the continuous pulse comprises a lower voltage than the startup voltage of the flash lamp.

In some aspects, the peak energy level of the starter pulse is 2 to 10 times the first peak energy level of the continuous pulse. In some aspects, the systems and methods further comprise a third stage including providing a third portion of the continuous pulse to the printed electronic circuit for a third time period to reach a third peak energy level.

In some aspects, a flash lamp sintering system is disclosed for use with a workpiece that includes a printed electronic circuit including at least one layer of nanoparticles. In some aspects, the flash lamp comprises a flash lamp; and a pulse generation module, the pulse generation module coupled to the flash lamp, the pulse generation module configured to cause the flash lamp to provide one or more continuous and configurable pulses to the printed electronic circuit including a layer of nanoparticles, the continuous and configurable pulse comprising at least two stages, the first stage including a first portion for a first time period at a first peak energy level; and the second stage including a second portion for a second time period at a second peak energy level, wherein the first peak energy level differs from the second peak energy level. In some aspects, the one or more pulses sinter the layer of nanoparticles such that the printed electronic circuit is conductive.

### BRIEF DESCRIPTION OF THE DRAWINGS

Features and advantages of certain embodiments are illustrated in the accompanying drawings.

FIG. 1 is a schematic illustration of two flash lamp parameters—peak energy and pulse width—that are controlled by embodiments of the disclosed systems and methods.

FIG. 2 is an illustration of sintering a thick film by controlling peak energy and pulse width, according to some embodiments of the present disclosure.

FIG. 3 is a schematic illustration of systems and methods according to some embodiments that result in a continuous pulse with an initially high peak energy level that is then adjusted to a lower peak energy level during the soak period.

FIGS. 4A-B illustrate certain advantages of embodiments of the disclosed methods and systems.

FIG. 5 illustrates pulse and temperature profiles in the disclosed methods and systems, as described in FIG. 4B.

FIG. 6A is a schematic illustration of systems and methods according to some embodiments that result in a continuous pulse with an initially low peak energy that is then adjusted to a higher peak energy pulse during sintering.

FIG. 6B is a schematic illustration of systems and methods according to some prior art methods that do not use continuous pulsing.

FIG. 7 is a schematic illustration of a continuous dual pulse-forming network including a start pulse generator in accordance with some embodiments of the disclosed methods and systems.

FIG. 8 is a schematic illustration of a continuous dual pulse-forming network including a start pulse generator in accordance with some embodiments of the disclosed methods and systems.

FIG. 9 is an exemplary screenshot depicting measured current versus time of a continuous pulse having a portion with a low peak energy followed by a high peak energy in accordance with some embodiments of the disclosed methods and systems.

FIG. 10 is an exemplary screenshot depicting a continuous flash lamp pulse having a portion with a high peak energy followed by a portion with a longer low peak energy pulse in accordance with some embodiments of the disclosed methods and systems.

FIG. 11 is an exemplary screenshot depicting three portions or stages of a continuous pulse in accordance with some embodiments of the disclosed methods and systems.

FIG. 12 is an example of a graph depicting resistivity versus low pulse energy for sintering a thick layer copper ink in accordance with some embodiments of the disclosed methods and systems.

FIG. 13 is a schematic illustration of three continuous pulses with various peak energy levels in accordance with some embodiments of the disclosed methods and systems.

### DETAILED DESCRIPTION

Electronic circuits with conductive ink can be printed using conventional printing processes, including but not limited to inkjet printing, screen process, and gravure. The conductive inks with small metallic particles are then sintered with radiant energy that can include combinations of pulsed light, high intensity continuous light, ultraviolet light, radiation, and thermal energy. The sintering causes the particles to bind together, thereby significantly increasing the conductivity (reducing the resistivity) of the ink compared to its pre-sintered form. A flash lamp can be used to perform the sintering. During such photonic sintering, high energy pulses of light sinter the small particles of material. The sintering can be performed at low temperatures relative to what it would take to sinter larger particles, thereby transforming printed lines of conductive ink into solid conductive traces. With relatively thick conductive layers, such as those printed using screen-printing techniques, it can be challenging to sinter an entire depth of the layers of ink. In these instances, it might not be sufficient to reach the typical sintering temperature. Instead, that sintering temperature should be maintained to allow the sintering heat to penetrate throughout the layer. If the temperature is not maintained, then un-sintered ink can remain underneath a top layer of sintered material. This incomplete sintering can lead to wasted ink, higher resistivity than desired and hence lower conductivity, and weaker adhesion of the material.

In the field of printed electronics, functional parameters include resistivity/conductivity of the lines, adhesion to the substrate, transparency, and flexibility. These parameters are interlinked during the sintering process. This means that an improvement of one parameter may lead to degradation of one or more of the others. For example, if resistivity is improved (i.e., decreased) more by one process, then adhesion or transparency may be reduced. In some aspects, these parameters may not be useful as inputs to a sintering system (e.g., user inputs on a touch panel screen). In some aspects, a goal is to improve the overall quality of all of these parameters simultaneously. In some aspects of the disclosure, better control over the functional parameters of sintering allows for more effective or complete sintering. In the disclosed methods and systems, in some embodiments, sintering parameters, including peak energy, pulse duration, and pulse profile or frequency, can be adjusted to provide effective and complete sintering.

In some embodiments, during sintering, peak energy is sufficient to heat a surface of an ink to its melting or sintering temperature. When particles are sintered, they form a continuous conductive path that has a conductivity that is higher than that of the particles in the ink before sintering. Establishing a defect-free sintering process can be difficult because conductive inks can be complex in nature. For example, certain metal inks, including copper inks, may require techniques to reduce oxidation or reduce solvents, carriers, and other impurities in the ink. Different types of ink may require a number of different methods to sinter it effectively. The present disclosure relates to systems and methods for more effective sintering by using at least one continuous pulse that allows for control of peak energy and pulse duration parameters that result in effective sintering. The present disclosure also relates to systems and methods of providing a continuous pulse for sintering.

Sintering can be performed with a flash lamp system that employs a high intensity flash of radiation to melt or sinter metallic nanoparticles to significantly increase the conductivity of the material. A benefit of pulsed light with a flash lamp is that the short duration tends to cause less heating. With inexpensive paper or plastic substrates, such lower heat can be desirable. For examples of ranges of conductive materials, purposes, substrates, and methods of applying energy (e.g., continuous or pulsed lasers or lamps), see, for example, U.S. Patent Publication Nos. 2003/0108664 and 2004/0178391, which are incorporated by reference in their entirety. The disclosed methods and systems can be used in conjunction with sintering methods known in the art.

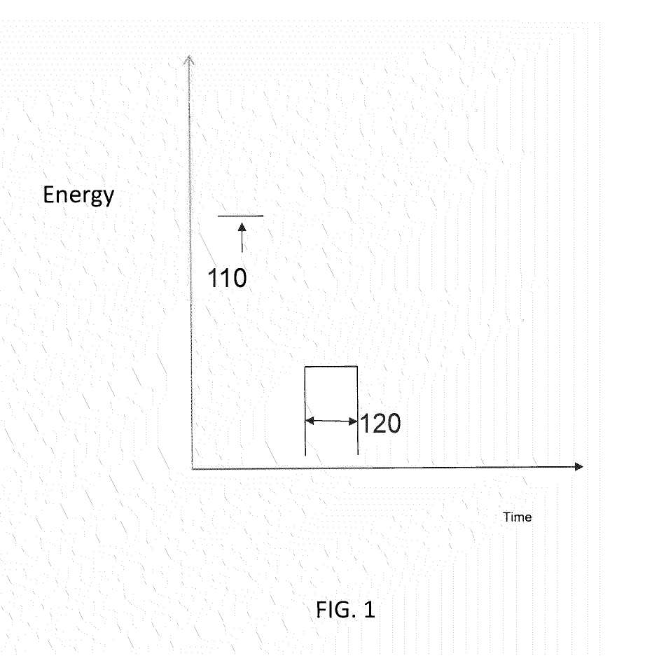

FIG. 1 illustrates two flash lamp parameters, peak energy 110 and pulse width 120, that are controlled by embodiments of the disclosed systems and methods. If the peak energy is too low, then the ink might not sinter. However, if the peak energy is too high, then the lamp could damage the substrate material and/or cause the metallic ink to evaporate. In some embodiments, methods and systems use a continuous pulse having various stages within a single pulse to control the width or duration of the pulse to provide a soak time sufficient for the bulk of the metallic ink to sinter. If the pulse width or duration is too short, the ink below the surface might not melt. If the pulse width is too long, the heat could damage the substrate and/or cause the surface of the metallic ink to overheat and evaporate.

In the present disclosure, in some embodiments, these two lamp flash parameters—peak energy and pulse duration—are adjusted to increase efficiency of the sintering process. During the sintering process, an electronic material, such as a metallic ink, is provided onto a substrate. The material can be provided using one or more technologies known in the art, including, but not limited to, screen-printing, inkjet printing, gravure, laser printing, inkjet printing, xerography, pad printing, painting, dip-pen, syringe, airbrush, flexography, evaporation, sputtering, etc. Various substrates can be used with the disclosed systems and methods. Each of these substrate materials can have a different preferred processing temperature. Substrates include but are not limited to low-temperature, low-cost substrates such as paper, and polymer substrates such as poly (diallyldimethylammonium chloride (PDAA), polyacrylicacid (PAA), poly (allylamine hydrochloride) (PAH), poly(4-styrenesulfonic acid), poly(vinyl sulfate) potassium salt, 4-styrenesulfonic acid sodium salt hydrate, polystyrene sulfonate (PSS), polyethylene imine (PEI), polyethylene terephthalate (PET), polyethylene, etc. Different materials to be sintered, including copper, silver, and gold, melt and evaporate at different temperatures. Other materials include but are not limited to palladium, tin, tungsten, titanium, chromium, vanadium, aluminum, and alloys thereof. The melting temperature of nanoparticles can vary by the size of the particles. Sintered lines can be printed with different widths and thicknesses.

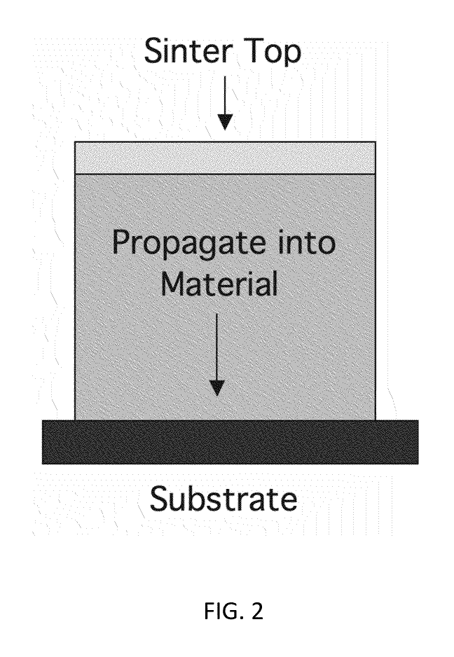

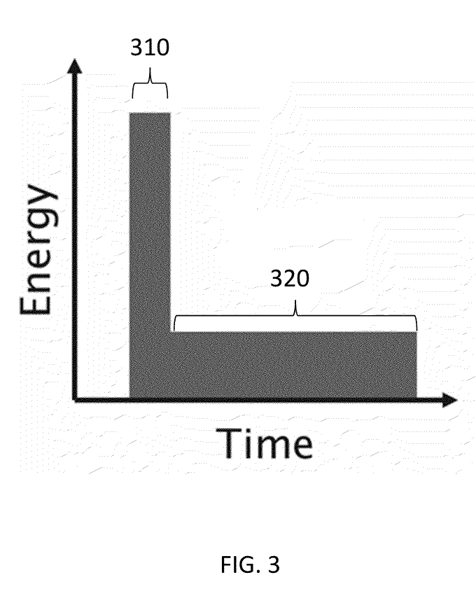

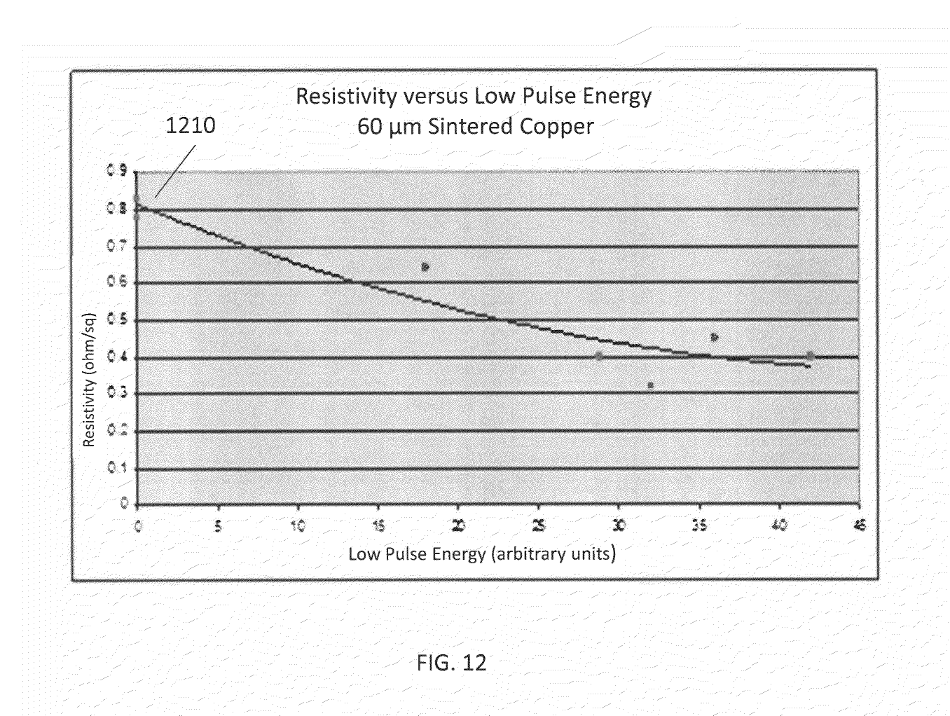

FIGS. 2 and 3 illustrate sintering of a thick film of metallic ink, according to some embodiments of the present disclosure, using a first portion of a continuous pulse 310 (FIG. 3) for sintering the film at a high peak energy for a first time period and second portion of a continuous pulse 320 (FIG. 3) for sintering the film at a lower peak energy for a second, longer time period. As described above, in some embodiments, the methods and systems allow control of peak energy and pulse width or time period for many applications, including for sintering thick films. In some embodiments, thick films comprise films including an ink thickness of 20 microns or more. Thick conductive layers, such as those printed using screen-printing techniques can pose challenges for achieving a depth of curing. For thick films, it may not be sufficient simply to reach a sintering temperature, the temperature may also have to be maintained or held to allow heat to penetrate into the thick ink layer and sinter more deeply into the material. If a sintering temperature is not maintained, un-sintered ink can remain under the top surface, which can lead to higher resistivity and weaker adhesion. For thick films, in some embodiments, a continuous flash lamp pulse having a stage 310 with a higher peak energy can be used to initiate sintering of the top surface. The continuous flash lamp pulse then sinters using a relatively lower peak energy of longer duration to follow the higher peak energy to maintain sintering throughout the material at appropriate sintering temperatures al. In some embodiments, applying a lower peak energy at a longer duration can be referred to as a hold region. FIG. 12 is an example of a graph depicting resistivity versus low pulse energy for sintering a thick layer copper ink, according to some embodiments. A first portion of a continuous pulse was applied at a relatively high energy followed by a second portion of the continuous pulse at a relatively low energy. The x-axis shows the added energy that came from the second portion of the continuous pulse in addition to the first portion of the continuous pulse. The energy from the first portion of the pulse was around 2200 Joules. The energy of the second portion of the continuous pulse varies from zero to 700 Joules. The maximum voltage on the secondary was approximately 1000 volts compared to 3 kilovolts on the primary pulse. The duration of the secondary pulse varied from 0 to 2 millisecond. The sintering process was improved with adjustment of the peak pulse with no energy in the hold region, as designated by the point labeled “1210.” As shown in FIG. 12, a 50% improvement in resistivity was shown as more energy was applied in the hold region.

In the instant disclosure, in some embodiments, methods and systems are disclosed that increase the efficiency of flash lamp sintering by adjusting the light intensity and duration of multiple phases of the at least one continuous flash lamp pulse. More specifically, in some embodiments, this increase in sintering efficiency is achieved by reducing the intensity of the flash during a hold period, as shown in FIG. 3.

In some embodiments, a single light pulse radiates at two distinct, independently-set energy levels. In some embodiments, a single light pulse can radiate at multiple distinct, independently-set energy levels. In other embodiments, the duration of the two or more portions of the continuous flash lamp pulse can also be independently set.

In embodiments where a first part of a pulse has high peak energy, and a second part of the light flash is low peak energy, the first part of the pulse is adjusted to raise the surface temperature of a metallic ink to at or near its sintering temperature. In some embodiments, to determine whether sintering temperature has been reached, an optical pyrometer can be used to measure the surface temperature of the ink as the light hits the metallic ink, and after the light hits the metallic ink. In other embodiments, to determine whether sintering temperature has been reached, after the first portion of the pulse, a change in conductivity will be noted when the surface of the ink has begun to melt, thereby indicating that sintering temperature had been reached. Based on such detection, a controller can cause changes in the peak energy level or pulse duration of the lamp pulse for future use or on the fly during operation. The second portion of the pulse provides energy sufficient to sinter the bulk of the ink without overheating the substrate or the metallic ink, and this second part of the pulse provides a light intensity that is lower than the first portion of the pulse. The desired temperature in the interior of the ink strip can more easily be achieved without overheating the surface of the ink strip or the substrate.

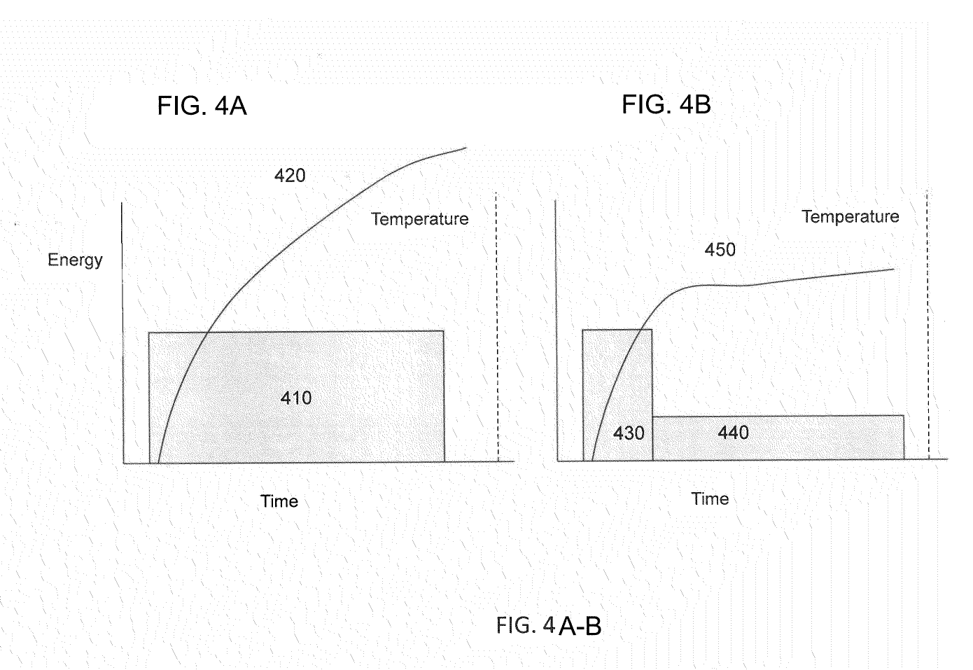

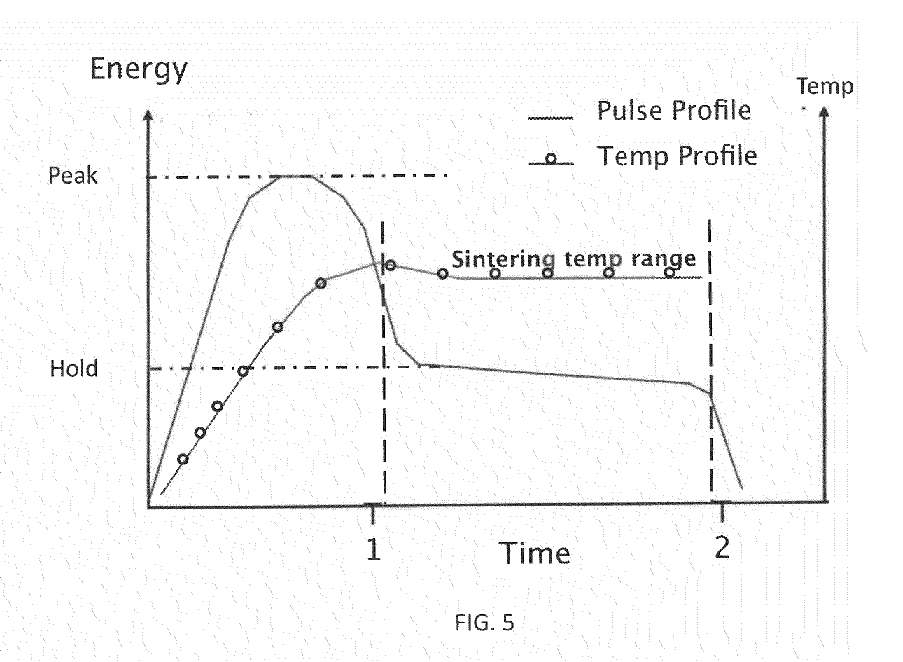

FIGS. 4A-4B illustrate an advantage of systems and methods as disclosed in the instant disclosure using at least one continuous pulse with multiple stages. In FIG. 4A, when one pulse-forming network (PFN) arrangement is used, increasing the pulse width 410 increases the rate of temperature rise 420. However, in FIG. 4B, which illustrates the system according to certain embodiments, sintering temperatures are reached rapidly with a pulse portion corresponding to PFN1 430, and then a pulse portion corresponding to PFN2 440 is used to maintain sintering temperature 450 at a controlled level set by the voltage setting on PFN2. This improved temperature control can allow for a wider defect-free process window. FIG. 5 illustrates other embodiments of specific portions of the pulse and temperature profiles in a continuous pulse with two portions. FIG. 5 also illustrates how the peak, hold, amplitude and durations of the pulse can be independently controlled.

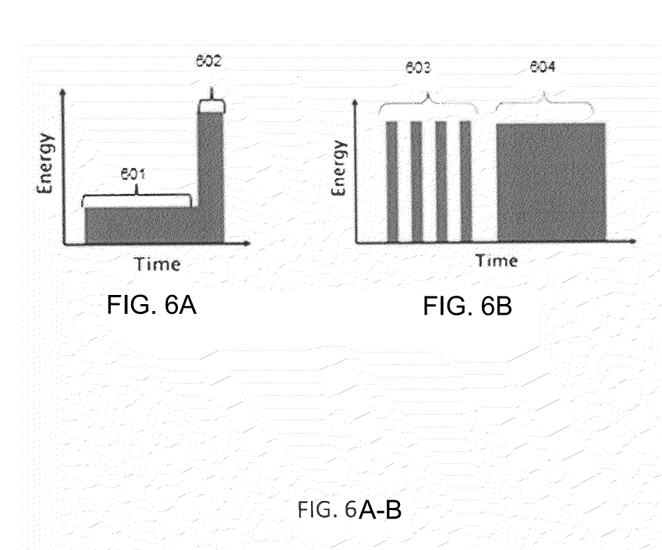

FIG. 6A is a schematic illustration of systems and methods according to some embodiments that result in an initially low peak energy pulse 601 that is then adjusted to a higher peak energy pulse during sintering 602. In some embodiments, the continuous pulsing disclosed herein can include a first portion 601 that is used to preheat material prior to sintering. For example, a lower intensity portion of a continuous pulse can be used to remove solvents prior to sintering at a higher intensity portion of a pulse. A lower intensity pulse can also be used to heat a substrate to just below sintering temperature to improve adhesion prior to sintering at a higher intensity pulse. The methods discussed herein can be used in conjunction with other methods. Methods and systems for using separate, non-continuous pulses, including a low pulse followed by a separate, non-continuous high pulse is discussed in more detail in U.S. patent application Ser. No. 13/586,125 entitled “Sintering Process and Apparatus,” filed on Aug. 15, 2011, and published as U.S. Publication No. 2013/0043221, the contents of which are incorporated by reference in its entirety.

FIG. 6B is a schematic illustration of systems and methods that, by contrast, do not use a continuous pulse with multiple stages or portions. FIG. 6B shows short duration pulses 603 at an energy level followed by a longer duration pulse 604 at the same energy level. The methods and systems disclosed herein can be used in conjunction with other methods for sintering. In some aspects, the disclosed methods and systems include a plurality of continuous pulses that can include multiple stages of compaction at a higher peak energy followed by a pulse of longer duration. In some embodiments, multiple, separate and continuous pulses of different intensities can be delivered by a single lamp. There are a number of photo-sinterable inks that require multiple pulses for effective sintering. For example, certain silver inks respond well to integrated energy over multiple pulses where using a single high energy pulse could damage the substrate. Generating an arbitrary number of pulses with different voltage peaks can achieve the task of compaction prior to sintering.

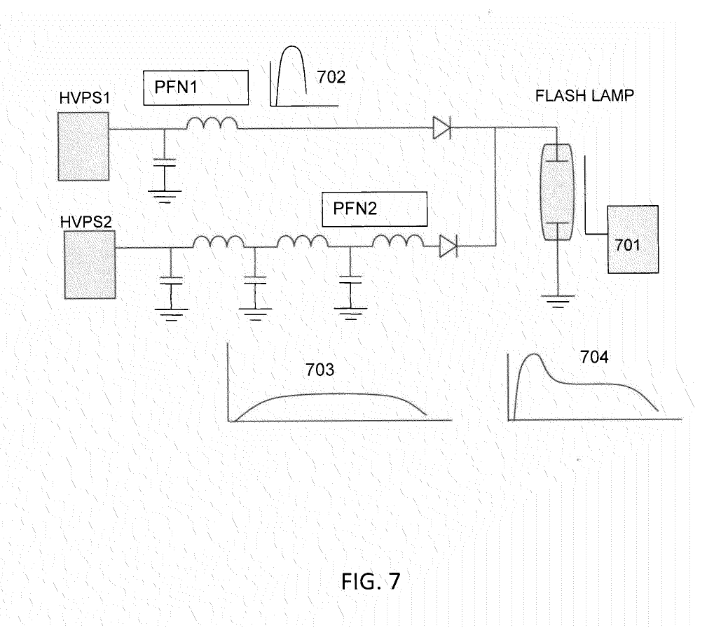

In some embodiments, the disclosed methods and systems use a continuous dual pulse-forming network (PFN) arrangement. The first portion of the continuous pulse generates high peak energy to initiate sintering at the surface of the metallic ink. The second portion of the continuous pulse heats the bulk of the material. FIG. 7 shows two high-voltage power supplies (HVPS), each with independent control of the high voltage set points. The flash is initiated via a trigger circuit 701. If run independently, PFN1 provides a pulse with high peak energy and low pulse duration, as shown by diagram 702, and PFN2 provides a pulse that has low peak energy and long duration, as shown by diagram 703. Once the lamp is triggered, PFN1, which is set at a higher voltage, starts to discharge though the lamp. Once the voltage of PFN1 goes below that set by the HVPS2, PFN2 will start to contribute, producing a long duration pulse, as shown by diagram 703. The peak energy and pulse width of the first part of the pulse is determined by the voltage set by HVPS1 in combination with PFN1. HVPS2 is used as a set point for the desired intensity of the second part of the pulse. The duration of the second part of the pulse can be controlled either by modification of the PFN2 network or by opening a switch in series with the lamp (switch not shown). Diagram 704 shows the result of the continuous, dual mode flash lamp sintering according to some embodiments.

In some embodiments, the duration of the first portion of the continuous flash lamp pulse is about 50 microseconds to about 500 microseconds, more specifically about 50 to about 100 microseconds. In some embodiments, the duration of the second portion of the continuous flash lamp pulse is about 1,000 microseconds to about 10,000 microseconds. In some embodiments, the duration of the second portion of the continuous flash lamp pulse is about 2 to 20 times, about 4 to about 15 times, or about 5 to about 10 times, the duration of first portion of the continuous flash lamp pulse. In some embodiments, the energy during the second portion is about 25% to about 75% of the energy of the first portion of the continuous pulse; about 30% to about 70% of the energy of the first portion of the continuous pulse; about 35% to about 65% of the energy of the first portion of the continuous pulse; about 40% to about 60% of the energy of the first portion of the continuous pulse; about 45% to 55% of the energy of the first portion of the continuous pulse; or about 50% of the energy of the first portion of the continuous pulse.

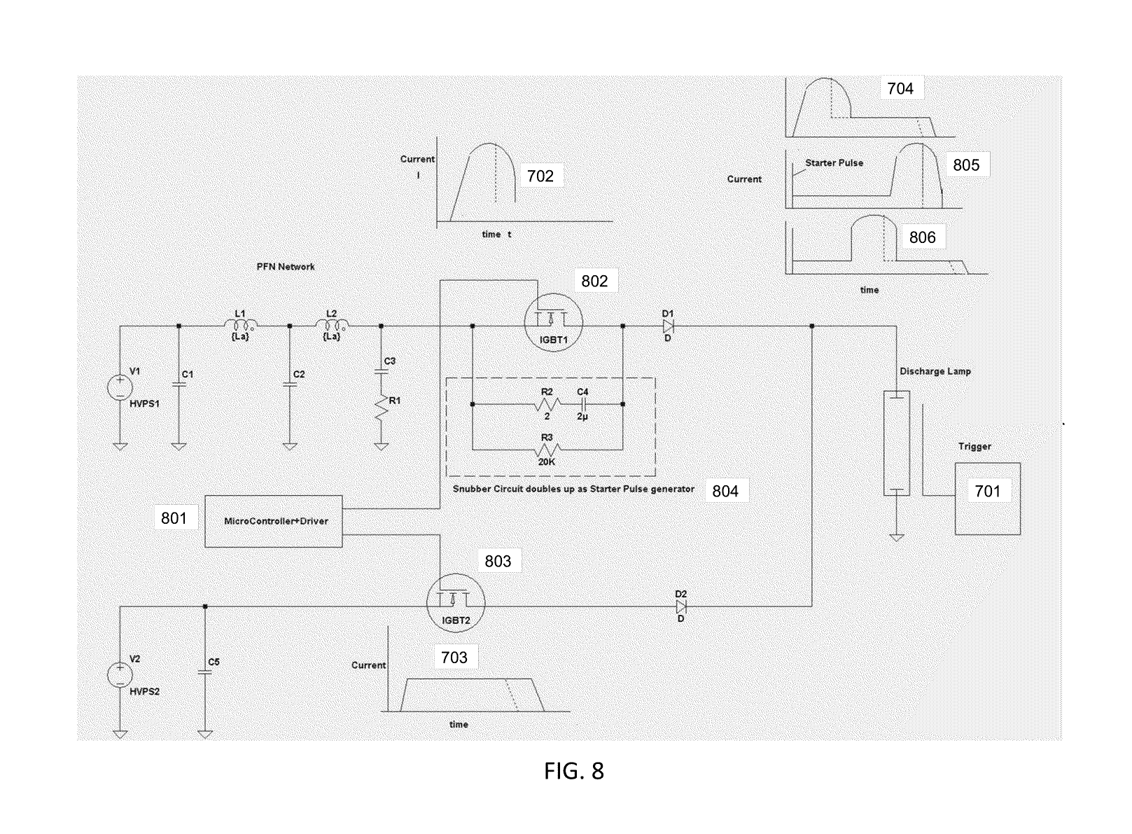

FIG. 8 is a schematic illustration of a continuous dual pulse-forming network including a start pulse generator in accordance with some embodiments of the disclosed methods and systems. FIG. 8 shows a trigger 701, a pulse with high peak energy and low pulse duration 702, a pulse with low peak energy and long duration 703, a high peak energy portion of a continuous pulse followed by a low peak energy portion of the continuous pulse 704, a control unit 801, a first switch such as first insulated-gate bipolar transistor 1 (IGBT1) 802, a second switch such as a second IGBT2 803, a start pulse generator 804, a low peak energy portion of a continuous pulse followed by a high peak energy portion of the continuous pulse 805, and a low peak energy portion of a continuous pulse, followed by a high peak energy portion of the continuous pulse and a low peak energy of the continuous pulse 806.

As described in FIG. 7, continuous dual pulse-forming network generates two pulse portions, which are concatenated into a single composite pulse via a diode connection. Two IGBT gates, IGBT1 802 and IGBT 2 803 act as switches, and are controlled by microcontroller driver circuit 801, allowing a flow of current from the two different HVPS branches as necessary. Other switches can also be used, such as a MOSFET. As a result, the net lamp current can be controlled to allow for several different kinds of pulse shapes. Depending on the timing, the pulse shapes can be additive in current as well as concatenated in time. For example, 704 shows a high peak energy portion of a pulse corresponding to a relatively high voltage generator followed by a lower peak energy tail of the pulse corresponding to a relatively low voltage generator. As discussed above, this type of waveform can be useful in carrying through the sintering process for a longer time at a fixed temperature, to allow deep penetration into thicker films. In 805, a low level current pulse is followed by a higher current discharge pulse. Also as described above, this type of waveform can be used to dry out the material or preheat it, prior to a sintering pulse. In 806, a low peak energy portion of a pulse is followed by a high peak energy portion of the pulse and then followed by a low peak energy portion of the pulse. This waveform can be used for preheating, sintering and post-heat annealing.

In some embodiments, the disclosed methods and systems address the problem of starting up a lamp when a first portion of an energy pulse is lower than a startup energy of the lamp. In cases where a first pulse portion is of a low voltage type, followed by a second higher voltage discharge pulse, such as in 805 and 806, the lamp may not start if the initial low voltage is lower than a startup voltage required for the lamp. A start pulse generator 804 can be used to start the lamp, delivering a short high pulse prior to a low pulse, as shown in 805 and 806. The start pulse generator 804 can act as a dual use circuit, functioning both as a starter circuit and as a snubber circuit on the High Voltage (HVPS1) IGBT1 802. Combining the snubber circuit and the starter pulse generator can eliminate complicated simmering (startup) circuits. Typical simmer circuits use a second power supply, with a method to inject the simmer voltage such as bulky inductors and/or diodes or thyristors with a start switch. The start pulse generator, as described herein according to some embodiments, uses an R-C network. There is no start switch required since the circuit starts automatically when the lamp trigger is activated. The snubber circuit prevents a sharp rise in current across a current switching device (in this case, IGBT1) when there is a sudden interruption in current flow. The snubber circuit, as shown in FIG. 8, provides an alternative current path such that an inductive component can be discharged safely. In FIG. 8, the snubber resistor R2, allows high voltage to trickle through to the discharge lamp tube anode. The snubber capacitor C2 allows a momentary rush of current for a very small time allowing the discharge tube to start conducting, at which point its resistance is dramatically lowered. At that point, a low voltage first pulse is allowed to drive the lamp.

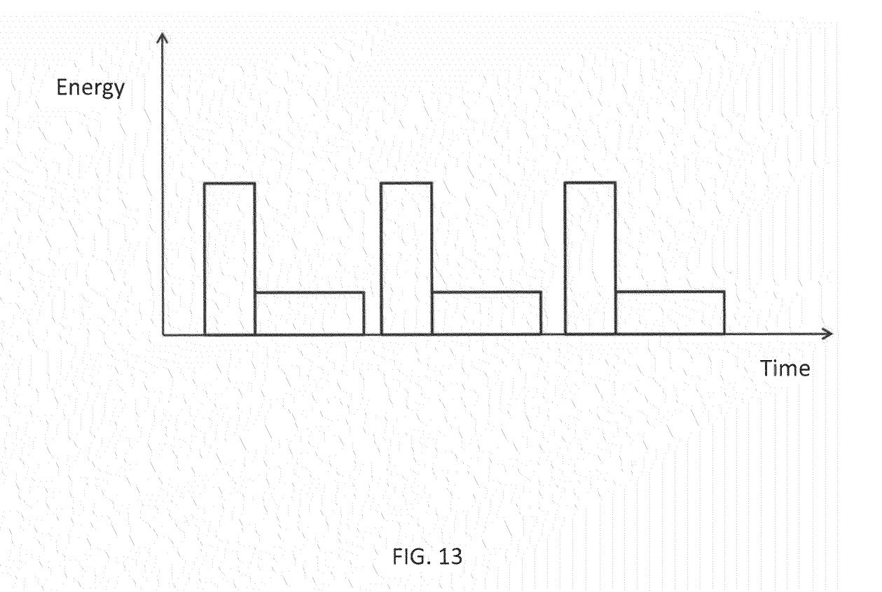

In some embodiments, the continuous dual pulse-forming network shown in FIG. 8 can be used to generate multiple pulse portions having various pulse peaks and frequencies, as shown in FIG. 13. Since the microcontroller controls both IGBT1 802 and IGBT2 803, pulse portions can be added to create a three, four or multiple concatenated pulse combinations of the two different voltages. In some embodiments, a continuous pulse can have multiple portions, including ranging from two to 40 portions.

In some embodiments, the methods and systems use multiple types of PFNs. FIG. 8 shows a purely capacitive branch, PFN2, and a standard PI-type network PFN, PFN1. Other types of PFNs, such as capacitive, inductive, or PI can be used to form the branches that produce different shapes of waveforms.

In some embodiments, more than two branches can be used. For example, some embodiments may require more than two voltages. More branches can be added to produce multiple-pulse portion waveforms of different voltages and widths.

In some embodiments, the continuous flash lamp pulse disclosed herein can be provided on a conveyor or other transporter operated in a continuous manner or in a stop-and-go manner Sensors and feedback can be used to modify the methods, including on the fly during operation. In illustrative implementations, sintering is performed in a conveyor system and/or using a light blocker to reduce stray sintering, as described, for example, in U.S. patent application Ser. No. 13/188,172 entitled “Reduction of Stray Light During Sintering,” filed on Jul. 21, 2011, and published as U.S. Publication No. 2012/0017829, the contents of which are incorporated by reference in its entirety. The methods and systems disclosed herein can be used with other methods known in the art, including systems and methods for blocking energy to a sufficient degree so as to avoid partial sintering of nanoparticles in workpieces or regions of workpieces before they are at a desired location to receive energy for sintering. In one or more embodiments, light blockers can be used to prevent an “intermediate phase” wherein nanoparticles are only partially sintered (or not sintered) after a first exposure to light energy but do not have improved conductivity after a second exposure to light energy. The disclosed methods and systems can be used in a conveyor system, including a conveyor frame. The conveyor frame can include a blower, power distribution cabinet, one or more emergency stop buttons.

In additional implementations, the dual-phase sintering systems and methods can be used in conjunction with the methods and systems disclosed in U.S. patent application Ser. No. 13/586,125 entitled “Sintering Process and Apparatus,” filed on Aug. 15, 2011, and published as U.S. Publication No. 2013/0043221, the contents of which are incorporated by reference in its entirety. As disclosed in the application, sintering can be done by first using a series of relatively low energy light pulses to pre-treat the target immediately prior to sintering. One advantage of this step is that the low energy pulses can effectively remove an organic coating from the nanoparticles, and the organic coating can act as a barrier or contaminant that result in poor substrate-to-metal adhesion and areas of low conductivity. Next, the nanoparticles can subsequently be sintered with one or more pulses of light. Thus, after pre-treatment with low energy light pulses, sintering can then be performed using the dual-phase sintering processes and methods disclosed herein.

Exemplary ranges of other pulsed lamp operating parameters include the following:
1. Energy per Pulse: 50 joules joule to 5,000 joules.
2. Pulse mode: single continuous pulse; bursts of continuous pulses; multiple continuous pulses; and continuous pulsing with multiple portions having various peak energy levels and durations.
3. Lamp Configuration (shape): linear, spiral, or u-shape.
4. Spectral Output: 180 nanometers to 1,000 nanometers.
5. Lamp Cooling: ambient, forced air, or water.
6. Wavelength Selection (external to the lamp): none or IR filter.
7. Uniformity Ranges ±0.1% to ±25% Center to Edge
8. Lamp Housing Window: none, pyrex, quartz, suprasil, or sapphire.
9. Top and Bottom Sequencing: Any combination in between from 0% to 100% top lamp to 0% to 100% bottom lamp.

Exemplary ranges of continuous pulse operating parameters with multiple stages include the following:
1. First stage energy output: 100 to 2000 joules, configurable in 5 milli-joule steps.
2. First stage duration: 0.1 to 2 milliseconds (ms), configurable in 0.05 ms steps.
3. Second Stage energy output: 100 to 5000 Joules, configurable in 15 milli-Joule steps.
4. Second Stage duration: 0.1 to 10 ms, configurable in 0.05 ms steps.
5. First Stage lamp voltage: up to 3000 Volts (V), configurable in 1 V steps.
6. Second Stage lamp voltage: up to 2400 V, configurable in 1 V steps.
7. Number of pulses in sequence: 1-40.
8. Spacing between pulses: 100 ms or more, configurable in 0.01 ms steps.
9. Pulse sequence modes: Single, repeat, continuous.
10. First Stage lamp voltage: up to 3000 V.
11. Second Stage lamp voltage: up to 2400 V.
12. Power output to lamp: up to 1500 watts.

The conductive inks that are used can be made up primarily of nanoparticles, with a majority of the particles having a diameter of 1 nm or less. But larger particles can potentially be used, including a majority less than about 10 nm, or 100 nm, or 1000 nm.

The methods and systems disclosed herein for continuous sintering can use the S-2300 High Energy Pulsed Light System available from Xenon Corporation. The following Examples illustrate embodiments of the disclosed methods and systems.

### Example 1

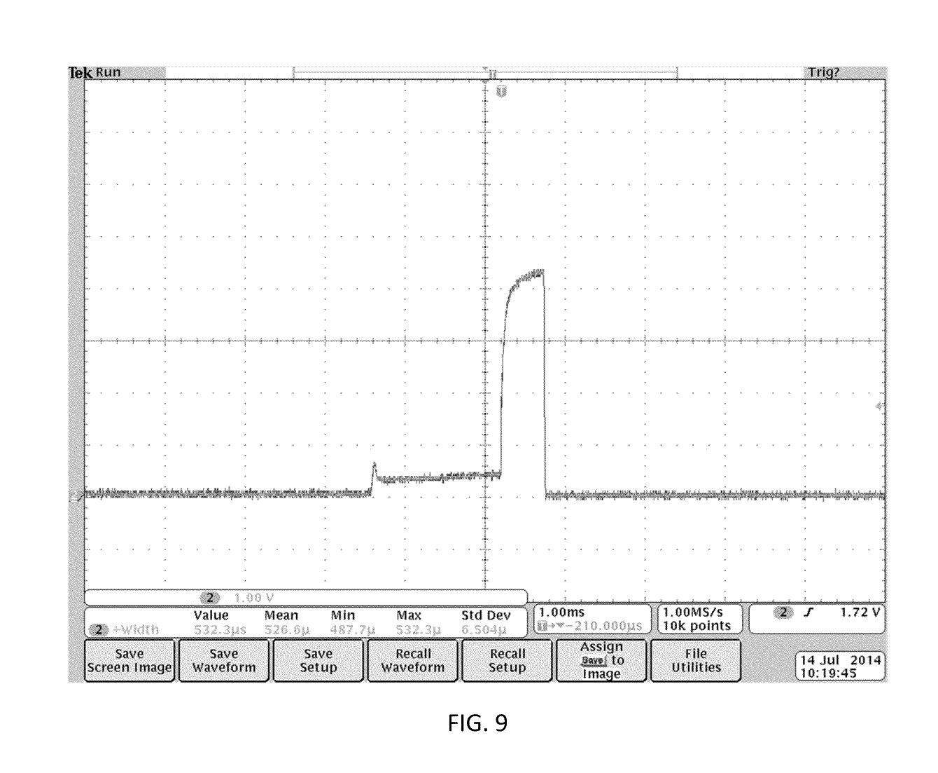

FIG. 9 is an exemplary screenshot depicting measured current versus time of a low level pulse followed by a high level pulse. The low level pulse had an initial kick provided by the Starter circuit, which started the conduction in the lamp. The low level pulse had a voltage of 400 Volts. The voltage normally required to start a similar discharge lamp was 1600 V. The low level pulse extended for 1.5 milliseconds in this discharge. The high level pulse used capacitor voltage in the range of 1600 V to 3000 Volts. The high level pulse was cut off after about 0.5 milliseconds using the IGBT circuit.

### Example 2

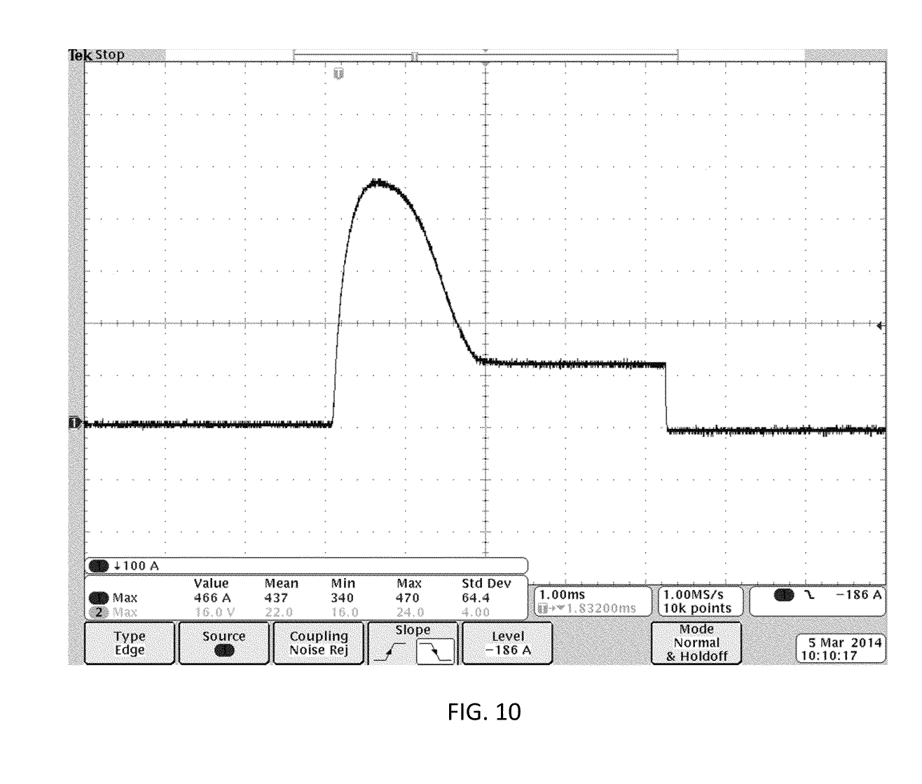

FIG. 10 is an exemplary screenshot depicting a continuous flash lamp pulse having a portion with a high peak energy followed by a portion with a longer low peak energy pulse. As described above, this waveform carried the sintering melt process through to the deeper layers without damaging or overheating the film or the substrate. The shape of the portion of the high peak energy had a smooth peak. In some embodiments, the shape of the high pulse can be altered depending on the combination of inductors and capacitors in that branch of the network. Capacitors were used to generate the low level pulse.

### Example 3

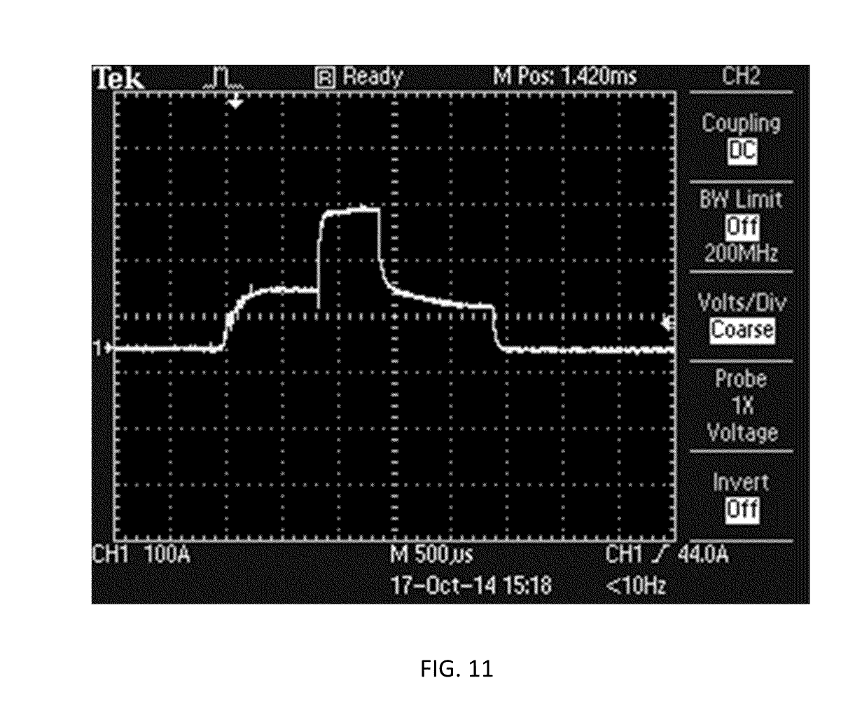

FIG. 11 is an exemplary screenshot depicting three portions of a continuous pulse. The first portion corresponded to a low level pulse. As described above, the low level pulse can be used to evaporate solvents, before the high level sintering pulse in the center was applied. The third portion of the pulse kept the energy flowing at a reduced rate so as to maintain equilibrium temperatures in order to carry the sintering process deeper into the material without overheating.

Having described embodiments of the present inventions, it should be apparent that modifications can be made without departing from the scope of the inventions described herein.

We claim:

1. A method of sintering comprising:
exposing a printed electronic circuit including a layer of particles to at least one continuous flash lamp pulse comprising at least two stages, the exposing including, for each pulse,
providing a first portion of the pulse to the printed electronic circuit for a first time period to reach a first peak energy level, and
providing a second portion of the pulse to the printed electronic circuit for a second time period to reach a second peak energy level, wherein the first peak energy level differs from the second peak energy level,
wherein the one or more pulses have sufficient energy to sinter the layer of nanoparticles such that the printed electronic circuit is conductive.

2. The method of claim 1, wherein the first peak energy level is higher than the second peak energy level of the continuous pulse.

3. The method of claim 2, wherein the first portion of the continuous pulse is sufficient to sinter an upper portion of a layer of particles, and the second portion of the continuous pulse is sufficient to sinter a lower portion of the layer of particles and is sufficient to maintain a low sintering temperature.

4. The method of claim 3, wherein the low sintering temperature ranges from 200 to 400 degrees Celsius.

5. The method of claim 2, wherein the first peak energy level of the first portion ranges from 1.5 times to 10 times the second peak energy level of the second portion of the continuous pulse.

6. The method of claim 2, wherein the first time period ranges from about 0.1 millisecond to 10 milliseconds, and the second time period ranges from about 0.1 milliseconds to 20 milliseconds.

7. The method of claim 1, wherein the first peak energy level is lower than the second peak energy level of the continuous pulse.

8. The method of claim 7, further comprising:
providing, prior to the first stage of the continuous pulse, a relatively short, high peak energy starter pulse to start up the flash lamp when an energy pulse corresponding to the first peak energy level of the continuous pulse comprises a lower voltage than the startup voltage of the flash lamp.

9. The method of claim 8, wherein the peak energy level of the starter pulse is 2 to 10 times the first peak energy level of the continuous pulse.

10. The method of claim 1, further comprising a third stage including providing a third portion of the continuous pulse to the printed electronic circuit for a third time period to reach a third peak energy level.

11. A flash lamp sintering system for use with a workpiece that includes a printed electronic circuit including at least one layer of particles, comprising:
a flash lamp; and
a pulse generation module, the pulse generation module coupled to the flash lamp, the pulse generation module configured to cause the flash lamp to provide one or more continuous and configurable pulses to the printed electronic circuit including a layer of particles, the continuous and configurable pulse comprising at least two stages, the first stage including a first portion for a first time period at a first peak energy level; and the second stage including a second portion for a second time period at a second peak energy level, wherein the first peak energy level differs from the second peak energy level,
wherein the one or more pulses sinter the layer of particles such that the printed electronic circuit is conductive.

12. The system of claim 11, in combination with a workpiece that includes a printed electronic circuit including a layer of particles.

13. The system of claim 11, wherein the pulse generation module further comprises:
a first pulse generator, the first pulse generator coupled to the flash lamp by a first switch, the first pulse generator configured to provide the first portion of the continuous and configurable pulse to the printed electronic circuit including the at least one layer of particles for the first time period at a first peak energy level when the first switch is closed; and
a second pulse generator, the second pulse generator coupled to the flash lamp by a second switch, the second pulse generator configured to provide the second portion of the continuous and configurable pulse to the printed electronic circuit board with the at least one layer of particles for the second time period at a second peak energy level when the second switch is closed, wherein the first peak energy level differs from the second peak energy level.

14. The system of claim 13, wherein the first pulse generator is a relatively high peak energy pulse generator and the second pulse generator is a relatively low peak energy pulse generator.

15. The system of claim 14, wherein the first portion of the continuous pulse is sufficient to sinter an upper portion of the layer of particles, and the second portion of the continuous pulse is sufficient to sinter a lower portion of the layer of particles and is sufficient to maintains a low sintering temperature.

16. The system of claim 15, wherein the low sintering temperature ranges from 200 to 400 degrees Celsius.

17. The system of claim 14, wherein the first peak energy level of the first portion ranges from 1.5 times to 10 times the second peak energy level of the second portion of the continuous pulse.

18. The system of claim 13, wherein the first pulse generator is a relatively low peak energy pulse generator and the second pulse generator is a relatively high peak energy pulse generator.

19. The system of claim 18, further comprising a start pulse module, the start pulse module coupled at one end to the high peak energy pulse generator, and coupled at a second end to the flash lamp, the start pulse module configured to produce a relatively short, high peak energy pulse to start up the lamp when an energy pulse corresponding to the first pulse generator includes a lower voltage than a startup voltage of the flash lamp.

20. The flash lamp system of claim 19, wherein the start pulse module comprises a snubber circuit.

21. The flash lamp system of claim 13, further comprising:
at least one additional pulse generator, the at least one additional pulse generator coupled to the flash lamp by at least one additional switch, the at least one additional pulse generator configured to cause the flash lamp to provide a third portion of the continuous and configurable pulse to the printed electronic circuit for a third time period to reach a third peak energy level.
